(19) United States
(12) Patent Application Publication
(10) Pub. No.: US 2025/0374496 A1
(43) Pub. Date: Dec. 4, 2025

(54) ELECTRICALLY TUNABLE ELECTROMAGNETIC INTERFERENCE SHIELDING DEVICES WITH TWO-DIMENSIONAL TRANSITION METAL CARBIDES AND NITRIDES (MXENES)

(71) Applicant: DREXEL UNIVERSITY, Philadelphia, PA (US)

(72) Inventors: Meikang HAN, Philadelphia, PA (US); Yury GOGOTSI, Warminster, PA (US); Danzhen ZHANG, Philadelphia, PA (US)

(21) Appl. No.: 18/874,284

(22) PCT Filed: Jun. 23, 2023
(86) PCT No.: PCT/US2023/026072

§ 371 Date: Dec. 12, 2024

Related U.S. Application Data
(60) Provisional application No. 63/366,852, filed on Jun. 23, 2022.

(51) Int. Cl. H05K 9/00

(52) U.S. Cl. CPC H05K 9/0081

(57) ABSTRACT

A tunable shielding component, comprising: a first portion of MXene; a second portion of MXene; and a separator disposed between the first portion of MXene and the second portion of MXene, the separator having an electrolyte disposed therein. An electronic device, comprising a tunable shielding component according to the present disclosure. A method, comprising applying a potential to a tunable shielding component according to the present disclosure so as to effect a change in the EMI SE of the tunable shielding component.

### CROSS-REFERENCE TO RELATED APPLICATIONS

The present application claims priority to and the benefit of U.S. patent application No. 63/366,852, “Electrically Tunable Electromagnetic Interference Shielding Devices With Two-Dimensional Transition Metal Carbides and Nitrides (MXenes)” filed Jun. 23, 2022. All foregoing applications are incorporated herein by reference in their entireties for any and all purposes.

### GOVERNMENT RIGHTS

This invention was made with government support under ECCS-2034114 awarded by the National Science Foundation. The government has certain rights in the invention.

### TECHNICAL FIELD

The present disclosure relates to the field of tunable EMI shielding components.

### BACKGROUND

Dynamically controlling interactions of electromagnetic (EM) waves with matter over the visible, infrared, and terahertz regions of the EM spectrum has been extensively explored for various applications, such as electrochromic windows, adaptive thermal management, wearable electronics, and others.(1-2) Of particular interest is tuning the response to EM waves with nanomaterials/nanostructures, aiming at developing highly integrated and adaptive devices. This tunability, however, is challenging when the wavelength (λ) of EM waves is much longer than the size scale of nanomaterials, e.g., microwaves (λ>1 mm).

Electromagnetic interference (EMI) shielding is essential for protecting electronic components against EM jamming with the explosive increase of wireless communication devices, particularly at gigahertz operation frequencies. Foam materials were developed to mechanically control the reflection and absorption of microwaves, enabling adjustable EMI shielding capability with deformation.(3) However, the increased thickness caused by porous structures hinders their practical applications in integrated electronics. To date, thin EMI shielding coatings remain ‘static’ protection. Alternatively, electrically controlling the interaction between EM waves and materials could be another approach that has been proven in optoelectronic and infrared devices.(4) Yet, the key feature of current EMI shielding materials is highly conductive, such as conventional metals (Al, Ni, Cu, etc.) and carbon materials (graphene, carbon nanotube, carbon fiber, etc.), dominating the incident EM waves with strong reflection. Generally, the electrical conductivity of metals is not tunable via external electric fields. The charge density can be adjusted in graphene through the insertion of ions between the layers but is limited in microwave range for EMI shielding due to the inert surface chemistry, few atomic layers, and electrical double-layer (EDL) charge storage. Hence, active manipulation of the interaction between centimeter-scale microwaves and thin films remains elusive due to the above fundamental challenges at gigahertz ranges.

### SUMMARY

MXenes, a large family of two-dimensional (2D) transition metal carbides and nitrides, have been newly emerged EMI shielding materials with a thinner thickness than metals and carbon materials.(5) The transition metal core layers in MXenes, coupled with the nature of 2D sheets, facilitate electron transport. Moreover, ionic channels between layers and abundant surface groups (—OH, —O, —F, etc.) make MXenes redox-active in aqueous electrolytes, enabling high-rate pseudocapacitive energy storage with high volumetric capacitance.(6) In comparison with EDL capacitor, the surface redox reaction with ion intercalation leads to electron transfer and the oxidation state change of surface layers accompanied by the change of interlayer spacing, which potentially affects the electrical conductivity of MXene electrode. Hence, combining metallic conductivity and pseudocapacitive charge storage may render MXene unique responses to incident EM waves, which consequently regulate EMI shielding behavior.

Here we introduce electrochemically driven EMI shielding devices made from MXene coating electrodes with aqueous electrolytes (FIG. 1A), enabling tunable and reversible EMI shielding capability. We systematically performed in situ measurements with different MXenes and electrolytes to verify the effects of electric double layer and pseudocapacitive behaviors on reflection and absorption. Furthermore, an electrical ‘switch’ with a transition from EMI shielding film to EM wave-transparent film is achieved through the oxidation of MXenes. More importantly, we demonstrate the control of reflection and absorption between nanometer-scale materials with centimeter-scaled EM waves in the X-band (8.2-12.4 GHz), which provide a realistic approach to a new generation of adaptive EM protection devices.

In one aspect, the present disclosure provides a tunable shielding component, comprising: a first portion of MXene; a second portion of MXene; and a separator disposed between the first portion of MXene and the second portion of MXene, the separator having an electrolyte disposed therein.

Also provided is an electronic device, comprising a tunable shielding component according to the present disclosure, e.g., according to any one of Aspects 1-13.

Further provided is a method, comprising applying a potential to a tunable shielding component according to the present disclosure (e.g., according to any one of Aspects 1-13) so as to effect a change in the EMI SE of the tunable shielding component.

### BRIEF DESCRIPTION OF THE DRAWINGS

The file of this patent or application contains at least one drawing/photograph executed in color. Copies of this patent or patent application publication with color drawing(s)/photograph(s) will be provided by the Office upon request and payment of the necessary fee.

In the drawings, which are not necessarily drawn to scale, like numerals may describe similar components in different views. Like numerals having different letter suffixes may represent different instances of similar components. The drawings illustrate generally, by way of example, but not by way of limitation, various aspects discussed in the present document. In the drawings:

FIG. 1. Tunable EMI shielding behaviors of devices using MXenes. (A) Schematic illustration of MXene-based EMI shielding device, which consists of MXene electrodes and an electrolyte-containing membrane. (B) Illustration of ions intercalation into MXene layers for tunable EMI shielding. Voltage-dependent EMI shielding effectiveness and the CV curves of the device using (C) V₂CTₓ electrode in 1 M H₂SO₄, (D) Ti₃C₂Tₓ electrode in 1 M H₂SO₄, (E) V₂CTₓ electrode in 19.8 M LiCl, and (F) Ti₃C₂Tₓ electrode in 19.8 M LiCl, showing the bidirectional tunability of EMI SE with different MXenes in different electrolytes.

FIG. 2. In situ characterization and the mechanism of bidirectional tunability. Voltage dependence of the reflection and absorption ratios using the device with (A) V₂CTₓ electrode in 1 M H₂SO₄ and (B) Ti₃C₂Tₓ electrode in 1 M H₂SO₄. In situ XRD and Raman measurements, showing variations of (C) d spacing and (D) Raman peak of the device with Ti₃C₂Tₓ electrode in 1 M H₂SO₄. (E) Illustration of the mechanisms for controllable EMI shielding behaviors: the charge transfer, oxidation state change, and layer spacing change.

FIG. 3. Thickness-dependent behavior and cycling stability. (A) Thickness dependent EMI SE and (B) cycling stability of the device with V₂CTₓ electrode in 1 M H₂SO₄.

FIG. 4. An EMI shielding ‘switch’ with MXene. (A) Voltage-dependent EMI SE of a device with Ti₃C₂Tₓ electrode in 1 M H₂SO₄, showing the recovery of EMI shielding film. In situ Raman (B) and XRD (C) analysis of the film oxidation process.

FIG. 5. MXene electrodes used in this work. (A) Schematics of MXene with different atomic layers. Optical and digital images of (B) V₂CTₓ, (C) Ti₂CTₓ, (D) Ti₃C₂Tₓ, (E) V₄C₃Tₓ, and (F) Nb₄C₃Tₓ. The scale bar is 20 m.

FIG. 6. XRD patterns of (A) MAX phases and (B) MXene coatings.

FIG. 7. MXene-based devices. Digital images of (A) a V₂CTₓ working electrode, (B) a Ti₃C₂Tₓ counter electrode, (C) assembled device for S parameters measurement, and (D) a 15*15 cm² device showing large-scale capability for practical applications.

FIG. 8. SEM image of the cross-section of a MXene film, showing the aligned layers.

FIG. 9. Tunable EMI shielding of device with V₂CTₓ electrode in 1 M H₂SO₄. Variation of EMI SE in the X band during (A) charge process and (B) discharge process. (C) Variation of the average SE_{A} and SE_{R} in the X band during charge and discharge process.

FIG. 10. Tunable EMI shielding of device with Ti₃C₂Tₓ electrode in 1 M H₂SO₄. Variation of EMI SE in the X band during (A) charge process and (B) discharge process. (C) Variation of the average SE_{A} and SE_{R} in the X band during charge and discharge process.

FIG. 11. Tunable EMI shielding of device with different electrodes in different devices. Voltage-dependent EMI shielding effectiveness and the CV curves of the device using (A) Ti₂CTₓ electrode in 1 M H₂SO₄, (B) Ti₂CTₓ electrode in 19.8 M LiCl, (C) V₄C₃Tₓ electrode in 1 M H₂SO₄, (D) V₄C₃Tₓ electrode in 19.8 M LiCl, (E) Nb₄C₃Tₓ electrode in 1 M H₂SO₄.

FIG. 12. In situ XRD patterns (A) and Raman spectra (B) of the device with Ti₃C₂Tₓ electrode in 1 M H₂SO₄.

FIG. 13. In situ Raman spectra of the device with the Ti₃C₂Tₓ electrode in 19.8 M LiCl.

FIG. 14. Cycling stability of the devices. (A) EMI shielding performance of the device with V₂CTₓ electrode in 1 M H₂SO₄ after different number of cycles, and the corresponding CV curves (B). (C) EMI shielding performance of the device with Ti₃C₂Tₓ electrode in 1 M H₂SO₄ after different number of cycles, and the corresponding CV curves (D).

FIG. 15. EMI shielding switch with Ti₃C₂Tₓ electrode in 1 M H₂SO₄. (A) Voltage-dependent EMI SE in the X band. (B) Variation of reflection, absorption, and transmission ratios during the oxidation process.

FIG. 16. EMI shielding switch with Ti₃C₂Tₓ electrode in 19.8 M LiCl. (A) Voltage-dependent EMI SE, showing the failure of EMI shielding. (B) Variation of EMI SE in the X band during the oxidation process.

### DETAILED DESCRIPTION OF ILLUSTRATIVE EMBODIMENTS

The present disclosure may be understood more readily by reference to the following detailed description of desired embodiments and the examples included therein.

Unless otherwise defined, all technical and scientific terms used herein have the same meaning as commonly understood by one of ordinary skill in the art. In case of conflict, the present document, including definitions, will control. Preferred methods and materials are described below, although methods and materials similar or equivalent to those described herein can be used in practice or testing. All publications, patent applications, patents and other references mentioned herein are incorporated by reference in their entirety. The materials, methods, and examples disclosed herein are illustrative only and not intended to be limiting.

The singular forms “a,” “an,” and “the” include plural referents unless the context clearly dictates otherwise.

As used in the specification and in the claims, the term “comprising” can include the embodiments “consisting of” and “consisting essentially of.” The terms “comprise(s),” “include(s),” “having,” “has,” “can,” “contain(s),” and variants thereof, as used herein, are intended to be open-ended transitional phrases, terms, or words that require the presence of the named ingredients/steps and permit the presence of other ingredients/steps. However, such description should be construed as also describing compositions or processes as “consisting of” and “consisting essentially of” the enumerated ingredients/steps, which allows the presence of only the named ingredients/steps, along with any impurities that might result therefrom, and excludes other ingredients/steps.

As used herein, the terms “about” and “at or about” mean that the amount or value in question can be the value designated some other value approximately or about the same. It is generally understood, as used herein, that it is the nominal value indicated ±10% variation unless otherwise indicated or inferred. The term is intended to convey that similar values promote equivalent results or effects recited in the claims. That is, it is understood that amounts, sizes, formulations, parameters, and other quantities and characteristics are not and need not be exact, but can be approximate and/or larger or smaller, as desired, reflecting tolerances, conversion factors, rounding off, measurement error and the like, and other factors known to those of skill in the art. In general, an amount, size, formulation, parameter or other quantity or characteristic is “about” or “approximate” whether or not expressly stated to be such. It is understood that where “about” is used before a quantitative value, the parameter also includes the specific quantitative value itself, unless specifically stated otherwise.

Unless indicated to the contrary, the numerical values should be understood to include numerical values which are the same when reduced to the same number of significant figures and numerical values which differ from the stated value by less than the experimental error of conventional measurement technique of the type described in the present application to determine the value.

All ranges disclosed herein are inclusive of the recited endpoint and independently of the endpoints. The endpoints of the ranges and any values disclosed herein are not limited to the precise range or value; they are sufficiently imprecise to include values approximating these ranges and/or values.

As used herein, approximating language can be applied to modify any quantitative representation that can vary without resulting in a change in the basic function to which it is related. Accordingly, a value modified by a term or terms, such as “about” and “substantially,” may not be limited to the precise value specified, in some cases. In at least some instances, the approximating language can correspond to the precision of an instrument for measuring the value. The modifier “about” should also be considered as disclosing the range defined by the absolute values of the two endpoints. For example, the expression “from about 2 to about 4” also discloses the range “from 2 to 4.” The term “about” can refer to plus or minus 10% of the indicated number. For example, “about 10%” can indicate a range of 9% to 11%, and “about 1” can mean from 0.9-1.1. Other meanings of “about” can be apparent from the context, such as rounding off, so, for example “about 1” can also mean from 0.5 to 1.4. Further, the term “comprising” should be understood as having its open-ended meaning of “including,” but the term also includes the closed meaning of the term “consisting.” For example, a composition that comprises components A and B can be a composition that includes A, B, and other components, but can also be a composition made of A and B only. Any documents cited herein are incorporated by reference in their entireties for any and all purposes.

The following disclosure is illustrative only and is provided without being bound to any particular theory or embodiment.

Controlling the reflection and absorption of incident electromagnetic waves at gigahertz frequencies into the thin film is a fundamental challenge. The ability to dynamically depress electromagnetic wave jamming is significant for protecting electronic devices but lacking in conventional electromagnetic interference (EMI) shielding materials.

We report MXene-based devices with various MXenes that enable the control of the interaction of electromagnetic waves with MXene layers, rendering the film with unprecedented bidirectional modulation of EMI shielding capability. The reversible tunability of EMI shielding effectiveness was realized by the electrochemically driven oxidation state change of transition metal and charge transfer in MXene layers with different electrolytes, accompanied by expansion and shrinkage of layer spacing. EMI shielding ‘switch’ was achieved through electrically controlled oxidation of MXene films. Our results offer opportunities to develop smart EMI protection devices with active modulation, which are different from the conventional ‘static’ shielding and can adapt to demanding environments.

A MXene composition is, generally, any of the compositions described in at least one of U.S. Patent Application Nos. 14/094,966 (filed Dec. 3, 2013), 62/055,155 (filed Sep. 25, 2014), 62/214,380 (filed Sep. 4, 2015), 62/149,890 (filed Apr. 20, 2015), 62/127,907 (filed Mar. 4, 2015) or International Applications PCT/US2012/043273 (filed Jun. 20, 2012), PCT/US2013/072733 (filed Dec. 3, 2013), PCT/US2015/051588 (filed Sep. 23, 2015), PCT/US2016/020216 (filed Mar. 1, 2016), or PCT/US2016/028,354 (filed Apr. 20, 2016), PCT/US2020/054912 (filed Oct. 9, 2020); preferably where the MXene composition comprises titanium and carbon (e.g., Ti₃C₂, Ti₂C, Mo₂TiC₂, and the like).

### Results and Discussion

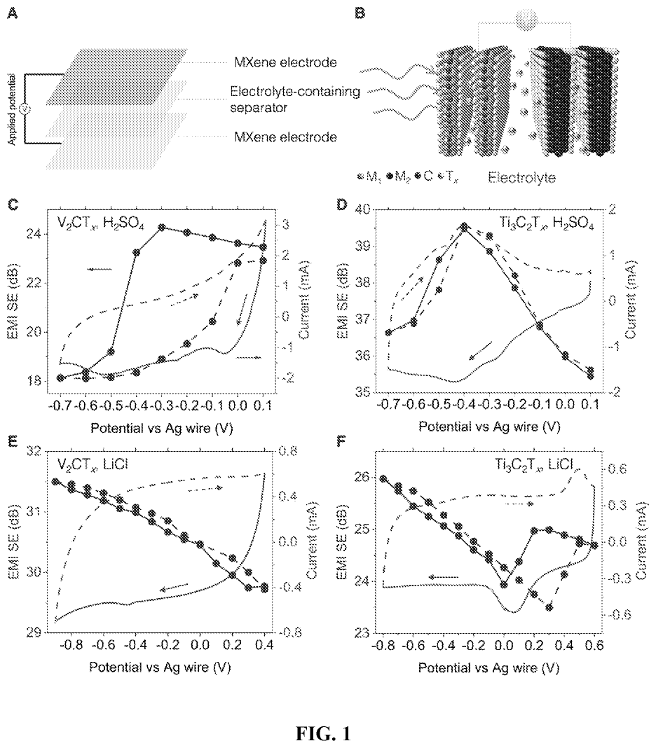

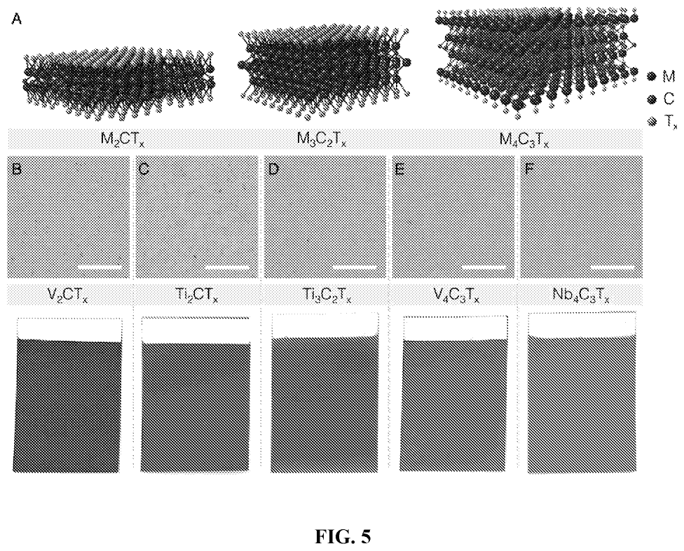

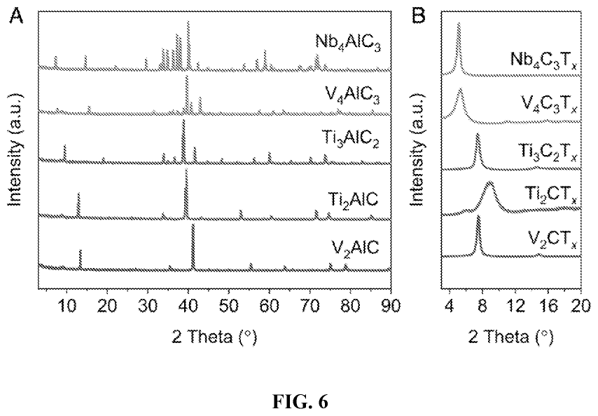

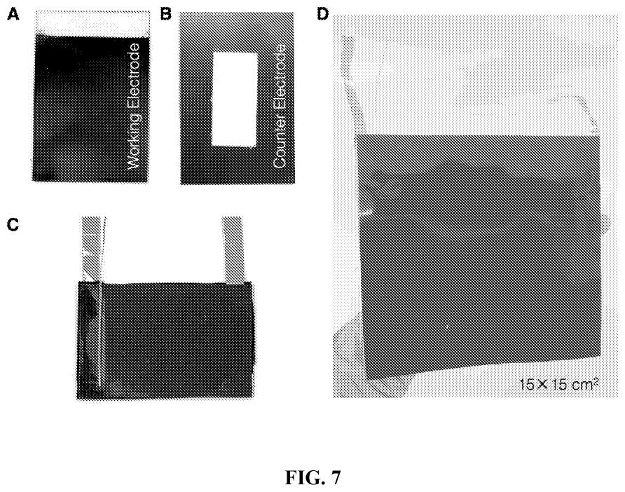

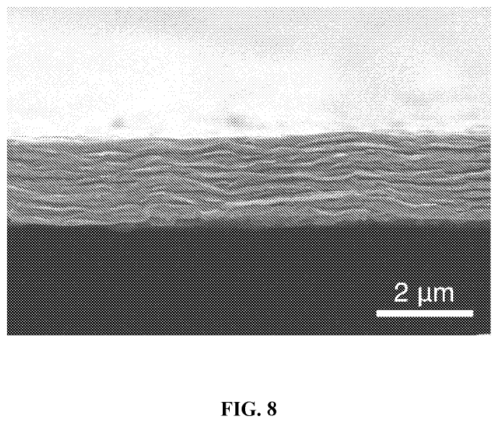

The EMI shielding device is assembled with a MXene-coated poly(ethylene terephthalate) (PET) working electrode, a Ti₃C₂Tₓ-coated counter electrode, an electrolyte-containing membrane, and Ag wire as a quasi-reference electrode (FIG. 1A). To track the interactions of MXene film with the incident EM waves under applied potentials, five MXenes (V₂CTₓ, Ti₂CTₓ, Ti₃C₂Tₓ, V₄C₃Tₓ, and Nb₄C₃Tₓ), which cover the typical stoichiometric MXene types (FIG. 5) and have different electrical conductivity and electrochemical behaviors, were selected as working electrode, respectively. All MXenes were synthesized through acid-etching of the corresponding MAX phases (FIG. 6) and a following delamination process (details were described in Supplementary Information). The delaminated MXene colloidal solutions were sprayed onto EM wave-transparent PET substrate to obtain MXene coatings which were sequentially assembled into the device (FIG. 7A-C). Noteworthily, to avoid that the highly conductive counter electrode affects the S-parameter measurement in waveguide cavity, a framed Ti₃C₂Tₓ coating with blank center was designed (FIG. 7B). A 15×15 cm² flexible MXene-based device (V₂CTₓ/Ti₃C₂Tₓ) was fabricated as well to show the large-scale availability (FIG. 7D). Scanning electron microscopy (SEM) image of the cross-section of MXene film shows the well-aligned MXene layers (FIG. 8). The intercalation of ions into MXene layers (charging the device) is achieved by applying a voltage to the MXene electrodes (FIG. 1). The ions are deintercalated from MXene layers during the discharge process, making the operation reversible and cyclic.

In situ EMI shielding measurement of the devices with different MXene electrodes in different electrolytes was carried out. For V₂CTₓ electrode in 1 M H₂SO₄ gel electrolyte at a scan rate of 10 mV s⁻¹, cyclic voltammogram (CV) shows a voltage window of 0.8 V (0.1−−0.7 V vs Ag wire). During the charge process, EMI shielding effectiveness (SE) slightly increases from 23.5 dB to 24.3 dB, when the voltage is applied from 0.1 V to −0.3 V. Remarkably, EMI SE has a sharp drop from 24.3 dB to 18.1 dB when the voltage is increased to −0.7 V, particularly from −0.3 V to −0.5 V. This process corresponds to the oxidation state change from the CV curve (˜−0.5 V). EMI SE value increases to the original status with the discharge process, indicating the operation is reversible. Moreover, in contrast to the slow intercalation of ions in other layered materials, even at a higher scan rate (50 mV s⁻¹), EMI shielding change of V₂CTₓ electrode is still fast and reversible, demonstrating it is available for instant regulation in practical applications. During this charge-discharge process, the EMI SE change is independent of the frequency (FIGS. 9A and 9B), implying that the layer spacing change arose from ion intercalation/deintercalation is uniform. EMI SE values of reflection (SE_{R}) and absorption (SE_{A}) show the same trend as the total EMI SE (FIG. 9C), which is different from the control of reflection and absorption by single mechanical deformation of materials.

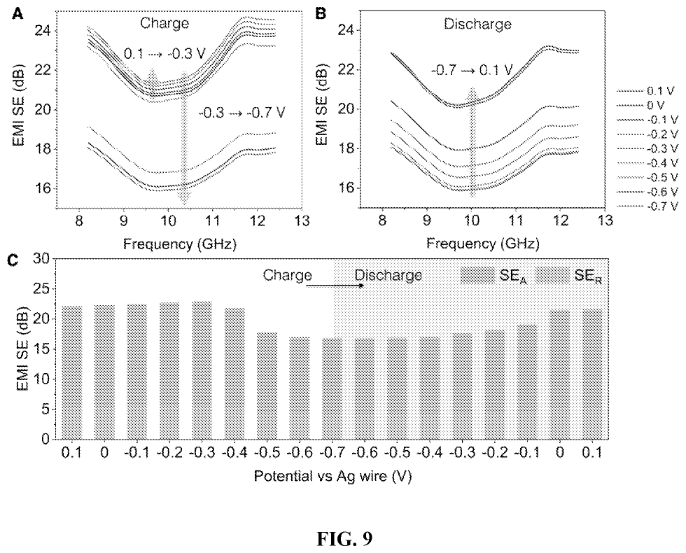

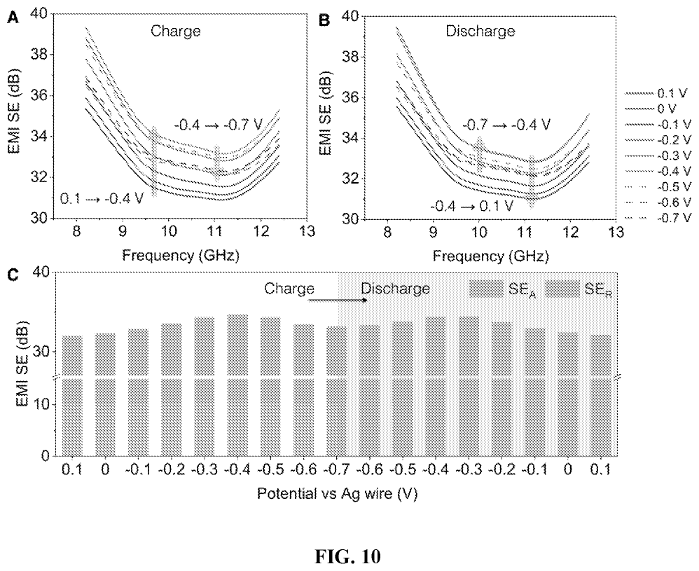

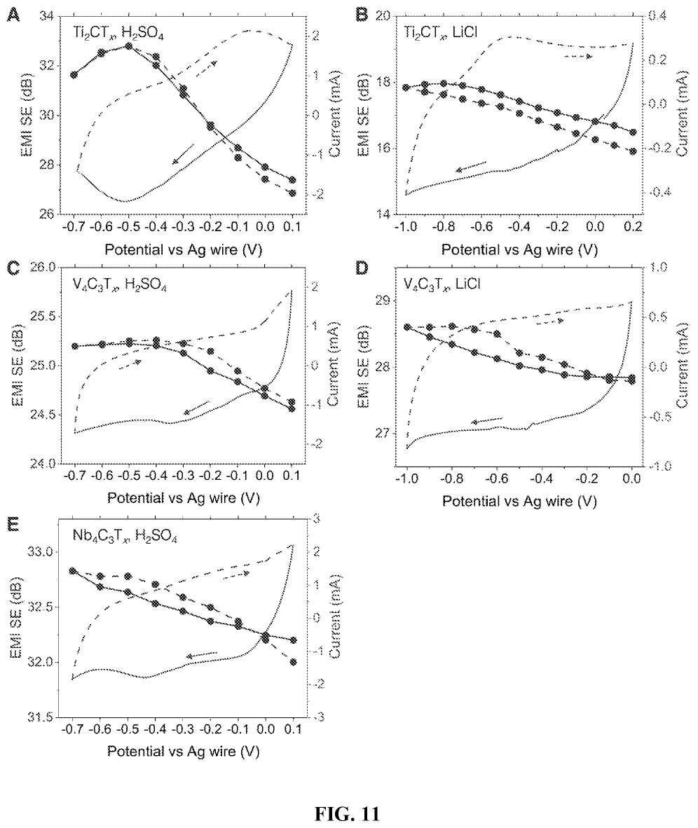

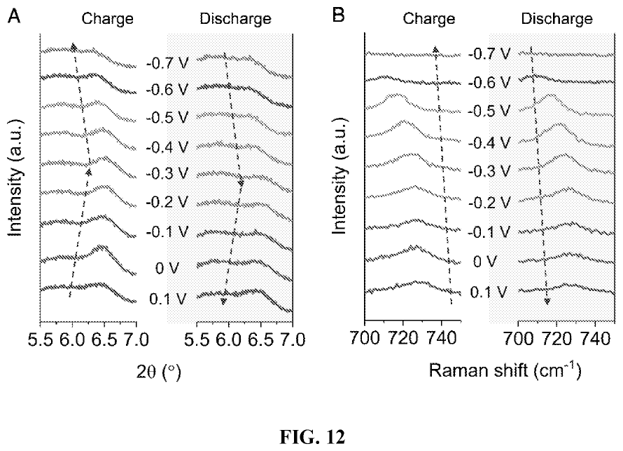

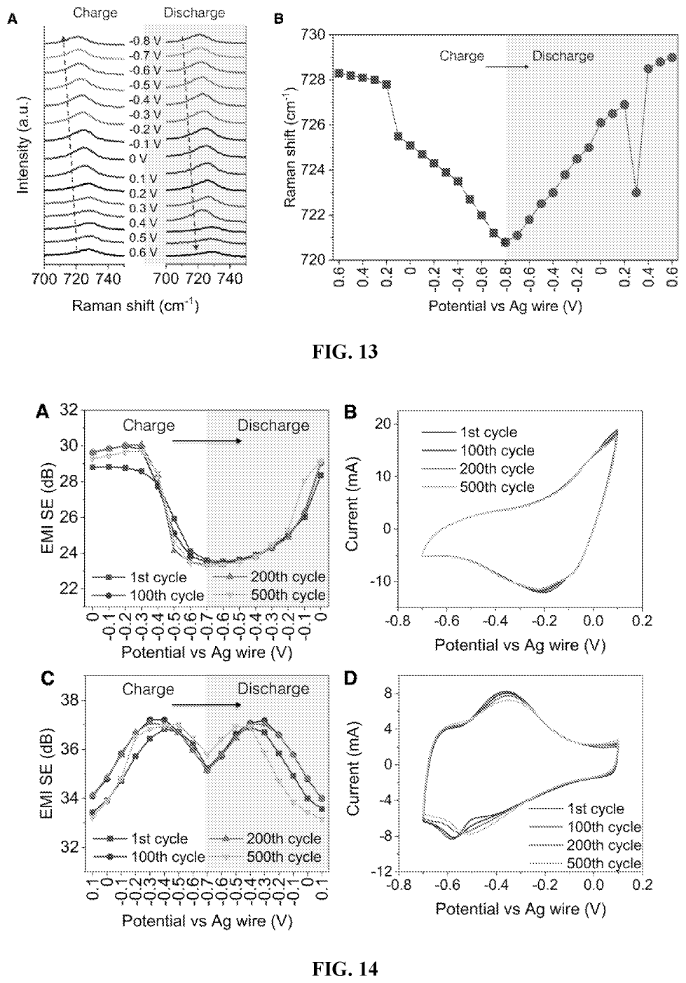

For Ti₃C₂Tₓ electrode with the same voltage window (FIG. 1D), from 0.1 V to −0.4 V, there is an apparent increase of EMI SE from 35.4 dB to 39.5 dB, implying a large increase of electrical conductivity of Ti₃C₂Tₓ film in this charge process. From −0.4 V to −0.7 V, EMI SE decreases from 39. 5 dB to 36.6 dB, similar to the process of V₂CTₓ-based device. During the discharge process, it fully repeats the change as the charge process and responds to the CV profile with a redox couple at around −0.4 V. Its total EMI SE is also frequency-independent (FIGS. 10A and B) and has the same change with SE_{R} and SE_{A} as the applied voltages (FIG. 0C). Compared with V₂CTₓ-based device, Ti₃C₂Tₓ-based device shows the same two processes of EMI shielding change (firstly increase and then decrease), but with a larger increase and relatively smaller decrease. The similar behavior can be found in Ti₂CTₓ-based device (FIG. 11A), while there is an almost monotonous process in V₄C₃Tₓ-based (FIG. 11C) and Nb₄C₃Tₓ-based devices (FIG. 11E). This is determined by their different electrochemical behavior which will be discussed later. V₂CTₓ, Ti₂CTₓ, and Ti₃C₂Tₓ electrodes have obvious pseudocapacitive ion intercalation, while only a pair of broad redox peaks appear for V₄C₃Tₓ and Nb₄C₃Tₓ in acidic electrolyte.

We further investigated EMI shielding performance of the devices in water-in-salt electrolyte (19.8 M LiCl) which was recently demonstrated to contribute to a desolvation-free Li⁺ insertion/desertion process for Ti₃C₂Tₓ MXene with a wider potential window. For V₂CTₓ electrode, EMI SE values monotonously increase/decrease in a range of 29.7−31.5 dB with the applied voltages (0.4−−0.9 V vs Ag wire), while the CV curve shows a typical EDL charge storage behavior (FIG. 1E). Ti₂CTₓ and V₄C₃Tₓ electrodes in WIS electrolyte show a similar trend of EMI SE change because of the EDL charging mechanism (FIGS. 7B and 7D). However, for Ti₃C₂Tₓ electrode, EMI SE values increase in the mass but have a fast drop from 0.2 V to 0.0 V during the charge process (0.6−−0.8 V). The discharge process shows an opposite process and an abrupt increase of EMI SE from 0.3 V to 0.5 V (FIG. 1F). These two anomalous changes correspond to a pair of strong peaks (−0.1 V and ˜0.5 V) in the CV curve which are related to the (de)intercalation of the solvated [Li(H₂O)₃]⁺ accompanied by large variation of d-spacing between MXene sheets.

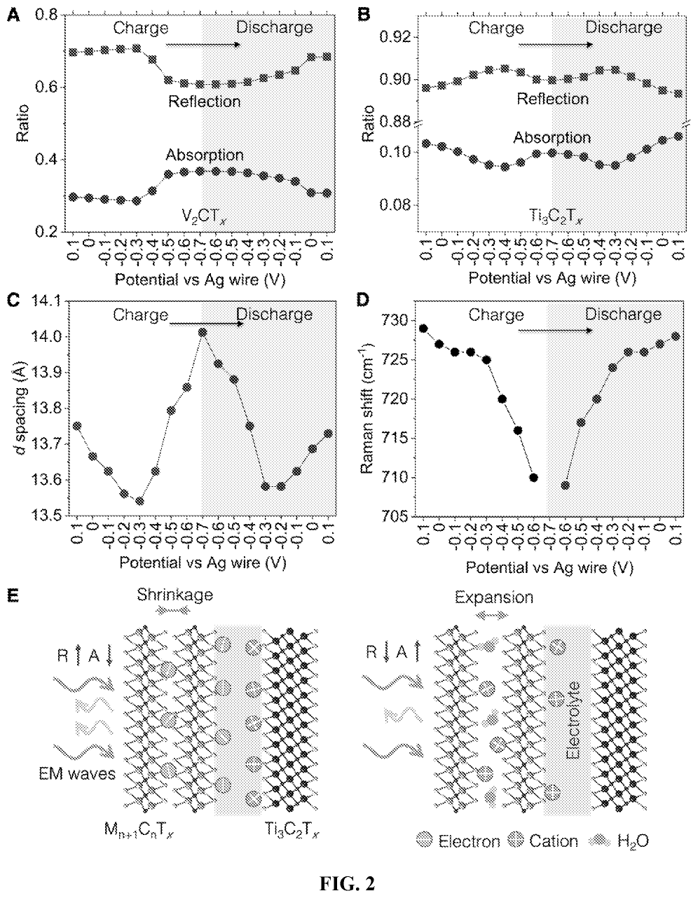

To understand the fundamental EM wave responses to the electrochemical behaviors, we calculated the reflection and absorption ratios of the incident EM waves for V₂CTₓ-based and Ti₃C₂Tₓ-based devices in 1 M H₂SO₄, respectively. The reflection ratios of both V₂CTₓ and Ti₃C₂Tₓ electrodes show the same trend as the total EMI SE, while the absorption ratios have opposite changes with the applied voltages (FIGS. 2A and 2B). In particular, the maximum gap of reflection/absorption ratios reaches −0.1, which is a significant change for thin film at gigahertz frequencies. By contrast, the absolute change of reflection/absorption ratios in Ti₃C₂Tₓ electrode is slight, which is distinct from the EMI SE values. This is determined by its ultrahigh electrical conductivity (>10000 S/cm), accounting for the strong reflection (>90%). Considering the diverse electrical conductivities and surface chemistry of different MXene compositions, it is believed that the control of reflection/absorption in MXenes can be further optimized for practical applications.

For more insights into the relationship between EM response and pseudo-intercalations, we performed in situ X-ray diffraction (XRD) and Raman measurements for Ti₃C₂Tₓ-based device during cyclic voltammetry. When Ti₃C₂Tₓ electrode in 1 M H₂SO₄ was charged, d-spacing decreased from 13.75 Å to 13.54 Å at 0.1−−0.3 V, then increased to 14.01 Å from −0.3 V to −0.7 V (FIGS. 2C and 12A). The discharge process shows a reversible change of d-spacing. We also visually exhibited the shrinkage and expansion of V₂CTₓ electrode during charge and discharge using a laser scanning confocal microscopy. This demonstrates that EMI SE increases with the shrinkage of MXene film and decreases with its expansion, which is attributed to the proton (de)intercalation. Raman spectra show a dramatic shift of the A_{1g} (C) peak which is assigned to out-of-plane vibrations of carbon, especially with an applied voltage from −0.3 to −0.7 V (FIGS. 2C and 12A). In agreement with the change of d-spacing, a drastic peak shift starts at −0.3 V, which is ascribed to the oxidation state change of titanium. Similarly, for Ti₃C₂Tₓ electrode in 19.8 M LiCl, the A_{1g} (C) peak shifts from ˜728 cm⁻¹ to ˜720 cm⁻¹ upon charging. It is noteworthy that there are larger peak shifts at ˜0.2 V (charge) and −0.3 V (discharge), respectively, which can correspond to the unusual pair of peaks in its CV curve.

According to the above in situ analysis, we propose interaction mechanisms of MXene-based devices with the incident microwaves based on distinct electrochemical behaviors (FIG. 2E). First, for MXenes with the EDL process, the intercalation of cations (H⁺, Li⁺, etc.) between negatively charged MXene layers under applied potentials shrinks the interlayer spacing due to the increase of electrostatic attraction, which leads to an increase in electrical conductivity and EMI SE eventually. Second, a special case is the insertion of desolvation-free cations in MXene sheets occurring in water-in-salt electrolytes, resulting in a decrease of EMI SE with the increase of d-spacing. Third, the pseudocapacitive behavior in MXenes continuously changes the oxidation state of transition metal on charging-discharging, and thereby gives rise to an expansion of interlayer spacing. Thus, the decreased EMI SE accompanied by the increase of absorption is achieved as a consequence of an abrupt decrease in conductivity. Significantly, as MXene layers offer different degrees of electrolyte confinement, there is a continuous transition between EDL capacitance and Faradaic intercalation. This feature facilitates the fast directional modulation of reflection and absorption in MXene devices upon charging/discharging.

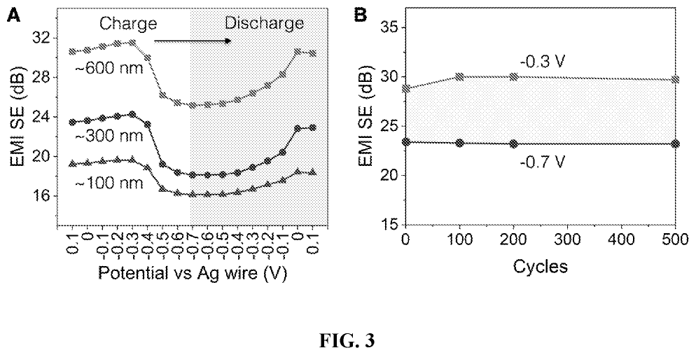

Given the importance of the ion confinements between MXene layers, we investigated the effect of film thickness on tuning EMI shielding of V₂CTₓ electrode in 1 M H₂SO₄ (FIG. 3A). It appears that the original EMI SE of the device increases with the increasing thickness from −100 nm to −600 nm. All the devices show the same trend for the EMI SE change with the applied voltages. However, the change range of EMI SE increases when the film is thicker. For example, the difference between the maximum value (31.51 dB at −0.3 V) and the minimum value (25.18 dB at −0.7 V) for −600 nm thick film is 6.33 dB, whereas that is 3.5 dB for −100 nm thick V₂CTₓ electrode. It demonstrates that the number of MXene layers significantly influences on controlling the EM wave response due to the varied degrees of intercalation and film deformation. The long-term stability of V₂CTₓ device in 1 M H₂SO₄ was evaluated by in situ EMI measurement with electrochemical cycles at 20 mV s⁻¹. It shows that the device operates steadily after 500 cycles and has a stable and reversible change of EMI SE (FIGS. 3B, 14A, and 14B) during charge/discharge cycles. Ti₃C₂Tₓ device in 1 M H₂SO₄ was confirmed to be endurable after 500 cycles as well, as it is correlated with its electrochemical stability (FIGS. 14C and 14D).

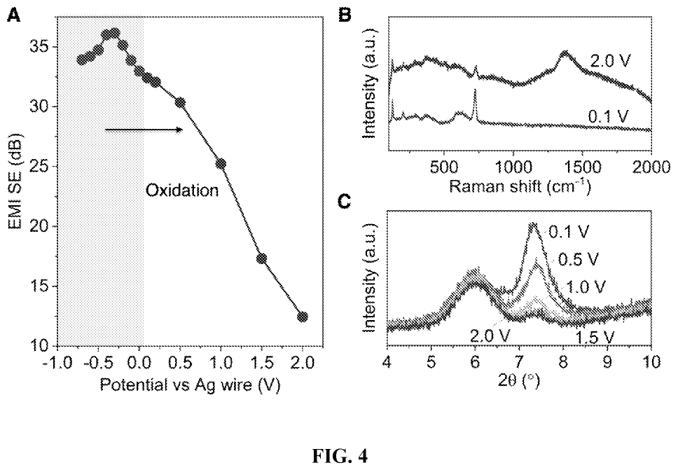

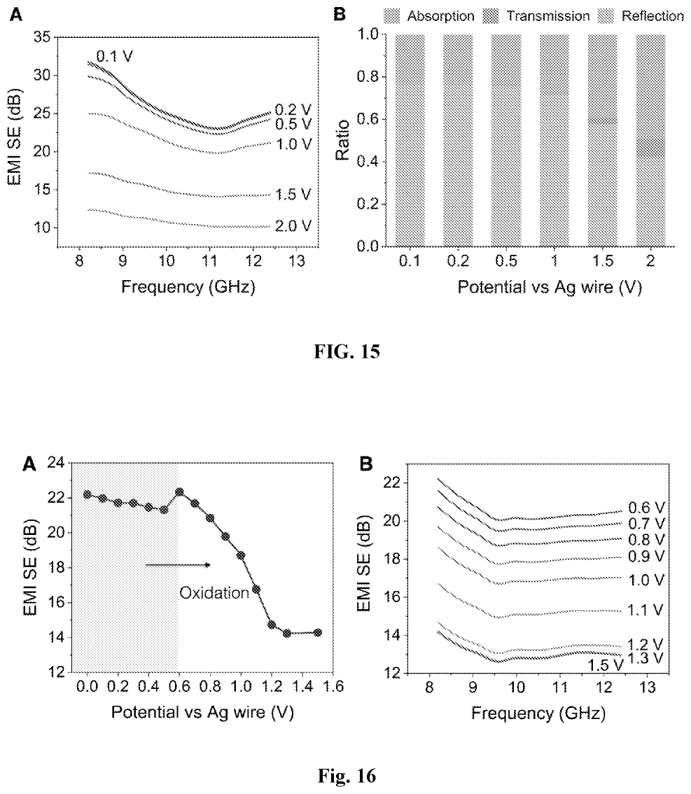

We further applied anodic potentials on Ti₃C₂Tₓ electrode in aqueous electrolytes to investigate their EM wave response with the oxidation of MXene. When the positive potentials are >0.1 V vs Ag wire, EMI SE value of Ti₃C₂Tₓ electrode in 1 M H₂SO₄ shows a sharp and continuous drop from 32.98 dB (0.1 V) to 12.45 dB (2.0 V) (FIG. 4A). Moreover, the trends of EMI SE values with increasing frequency are slightly different (FIG. 15A), which may be ascribed to EM wave scattering from ununiform oxidation of Ti₃C₂Tₓ electrode. Significantly, the average ratios of absorption, reflection, and transmission of the device at 2.0 V are 0.49, 0.43, and 0.08, respectively, while the ratios of absorption and reflection at 0.1 V are 0.23 and 0.77, and the transmission is negligible. Raman spectra show that the relative intensity of A_{1g} (C) peak at −723 cm⁻¹ decreases and a broad peak appears at around 1378 cm¹ (FIG. 4B), when the applied potential is 2.0 V. This is due to the exposed amorphous carbon accompanied by the surface oxidation of Ti₃C₂Tₓ. In situ XRD patterns show two broad peaks at ˜6.0° and ˜7.3° where are assigned to Ti₃C₂Tₓ counter electrode and working electrode, respectively (FIG. 4C). Notably, the peak intensity of working electrode decreases with the applied potentials whereas no obvious change can be observed for counter electrode. It indicates that the disorder degree of stacked Ti₃C₂Tₓ sheets increases with the oxidation process under positive potentials. Ti₃C₂Tₓ device in 19.8 M LiCl shows a similar phenomenon in that EMI SE value decreases from 22.33 dB (0.6 V) to 14.28 dB (1.5 V) (FIG. 16). These results indicate that the MXene devices can convert from EMI shielding to quasi-EM wave transmission through the electrochemical oxidation of MXenes. The device can potentially operate as a dynamic indicator for EMI shielding switch, although the oxidation process is irreversible. Furthermore, the sensitivity can be tuned for specific scenarios through the control of oxidation with different MXene compositions in different electrolytes.

It is important to note that electrochemical behaviors of MXenes still need a detailed understanding, given the fact that MXene family has various compositions, structures, and surface groups. It means that the control of EM wave response at gigahertz frequencies can be further optimized by modifying MXenes and confined electrolytes. In addition, although MXenes have been demonstrated to be superior EMI shielding materials, there is a lack of the physical understanding of “microwave-MXene interactions.” The combination of varied electronic conductivities and redox-active transition metal atoms makes electrochemically driven MXene-based devices promising to address the fundamental response of nanometer-scaled MXene sheets with centimeter-scaled EM waves. Furthermore, we envision that our concept can combine with metasurface by patterning MXene electrodes to achieve precise local control of reflection, absorption, and transmission for microwaves in thin films, which can be an exciting direction to explore in future studies.

### CONCLUSIONS

In summary, we have demonstrated electrochemically driven MXene devices to control the response to the incident EM waves at gigahertz ranges, enabling the modulation of EMI shielding effectiveness. Bidirectional tunability of EMI SE is achieved with a continuous transition from EDL to pseudocapacitive charge storage in MXene-based cells with aqueous electrolytes. Particularly, pseudocapacitive behavior in MXene electrode changes the oxidation state of transition metal accompanied by ion intercalation and film deformation, and thus increases the ratio of absorption and decreases EMI SE. An EMI shielding switch has been designed by utilizing the oxidation of MXenes with applied anodic potentials. Our results offer an insight into the fundamental understanding of the interactions of microwave with thin film and build a platform to develop adaptive EMI shielding devices with dynamic regulation.

### Materials and Methods

### Materials

For synthesis of the MAX phases, Ti (99.5%, Alfa Aesar), V (99.5%, Alfa Aesar), Nb (99.99%, Beantown Chemical), A1 (99.5%, Alfa Aesar), graphite (99%, Alfa Aesar), and TiC (99.5%, Alfa Aesar) powders were used.

For topochemical synthesis of MXenes, hydrofluoric acid (HF, 48.5−51%, Acros Organics), hydrochloric acid (HCl, 36.5−38%, Fisher Chemical), lithium chloride (LiCl, 99%, Acros Organics), lithium fluoride (LiF, 98.5%, Alfa Aesar), tetramethylammonium hydroxide (TMAOH, 25 wt %, Acros Organics) were used.

For the fabrication of the device, sulfuric acid (H₂SO₄, 98%, Fisher Chemical), polyvinyl alcohol (PVA, Alfa Aesar), poly(ethylene terephthalate) (PET, 100 m thick, TruLam) were used.

### Synthesis of MAX Phases

Prior to synthesis, all precursor powders (Table Si, below) were weighed, and then ball milled with zirconia balls at 50 rpm for 18 h. The powder mixture was then transferred to alumina crucibles, which were placed into a high temperature furnace. Argon was flowed through the furnace for 1 h before heating, then was kept flowing through the furnace during synthesis. The heating rate was 3° C. min⁻¹. Depending on the chemistry and composition, different temperatures and annealing times were used (details in Table S1, below). After cooling, the samples were milled and then sieved to <75 km.

TABLE S1
The synthesis conditions of MAX phases used in this work.

| | | | | Annealing | Amealing |
|---|---|---|---|---|---|
| | | | | temperature | time |
| Type | MAX phase | Precursors | Atomic ratio | (° C.) | (h) |
| 211 | Ti₂AlC | Ti:Al:C | 2:1.1:0.9 | 1550 | 2 |
| | V₂AlC | V:Al:C | 2:1.1:0.9 | 1550 | 2 |
| 312 | Ti₃AlC₂ | TiC:Al:Ti | 2:2.2:1.25 | 1380 | 2 |
| 413 | Nb₄AlC₃ | Nb:Al:C | 4:1.1:2.7 | 1650 | 4 |
| | V₄AlC₃ | V:Al:C | 4:1.5:3 | 1500 | 2 |

### Synthesis of MXenes

Synthesis of Ti₃C₂Tₓ and Ti₂CTₓ. Ti₃C₂Tₓ and Ti₂CTₓ were synthesized by etching the corresponding MAX phase powders (Ti₃AlC₂ and Ti₂AlC) with HF and HCl. Typically, 12 mL of HCl, 2 mL of HF and 6 mL of deionized (DI) water were mixed with stirring firstly. After that, 1 g of MAX powder was gradually added to the mixed solution and kept stirring for 24 h at room temperature. After the etching is done, the reacted solution was washed by centrifugation at 3500 rpm for 2 min. This washing process was repeated until pH value is >6. The centrifuged sediment was added into a solution of LiCl (1 g) in DI water (50 mL). The mixture was kept shaking for 30 min at room temperature. After that, the solution was washed by centrifugation at 3500 rpm for 10 min. The centrifugation was repeated until pH value is >6. After the sediment was swelled, the solution was centrifuged at 7500 rpm for 3 min finally. The supernatant was used for the preparation of MXene electrodes.

Synthesis of V₂CTₓ, V₄C₃Tₓ, and Nb₄C₃Tₓ. V₂CTₓ, V₄C₃Tₓ, and Nb₄C₃Tₓ were synthesized by etching the corresponding MAX phases (V₂AlC, V₄AlC₃, and Nb₄AlC₃) with HF. Typically, 1 g of V₂AlC powder was added into 20 mL of HF. The mixture was stirred at 35° C. for 48 h. After etching, the reacted solution was repeatedly washed with DI water through centrifugation at 3500 rpm for 2 min until pH >6. After washing, the sediment was dispersed in the mixture of 10 mL of DI water and 0.5 g of TMAOH, and then stirred for 24 h. After that, the mixture was washed repeatedly with DI water by centrifugation at 10000 rpm for 10 min until pH<8. At last, the supernatant was collected after centrifugation at 3500 rpm for 10 min. For V₄AlC₃ and Nb₄C₃Tₓ, the etching and delamination procedures were similar to V₂CTₓ, except the etching time was 7 days and the delamination time was 48 h.

### Fabrication of Devices

MXene films were fabricated by a spray-coating method. Firstly, PET sheet was cut into pieces with 4.5 cm×3 cm and cleaned by bath sonication (Branson 2510 Ultrasonic Cleaner, 100W) in DI water for 15 min, and then dried with compressed air. The cleaned PET pieces were plasma treated (Tergeo Plus, Pie Scientific) at 100 W with Ar/O₂ (3/5 sccm) for 5 min to make the surface hydrophilic. The pre-treated pieces were spray-coated with as-synthesized MXenes colloidal solution followed by air drying. For spray-coating process of counter electrode, a square mask (2.5 cm×1.2 cm) was applied to the middle of PET piece to get framed Ti₃C₂Tₓ coating. After spray-coating, MXenes films were dried in a vacuum oven overnight before performing experiments.

EMI shielding devices were fabricated using different MXene films as working electrode (WE), silver wire as reference electrode, and Ti₃C₂Tₓ films with blank region in the middle as counter electrode (CE). Electrolyte-containing membrane (MCE membrane, Thermal Scientific, 0.22 μm pore size) was used as a separator between electrodes. Copper foil was used to connect electrodes and potentialstat. The acidic electrolyte was fabricated by mixing 10 mL of 1 M H₂SO₄ and 0.5 g of PVA with stirring at 80° C. for 12 h. The water-in-salt electrolyte was fabricated by mixing 10 mL of 19.8 M LiCl and 0.5 g of PVA with stirring at 80° C. for 12 h.

### Characterization

X-ray diffraction (XRD) patterns of MAX phases and MXene films were measured using a Rigaku SmartLab (Tokyo, Japan) operating at 40 kV/30 mA with Cu Kα radiation. Raman measurement was carried out with an inverted reflection mode Renishaw (2008, Gloucestershire, U.K.) instrument, equipped with 63× (NA=0.7) objectives and a diffraction-based room-temperature spectrometer. The laser wavelength was 785 nm, and the laser power was kept around 0.1 mW. A 3D laser scanning confocal microscopy (Keyence, VK-X1000, Japan) was used to observe the surface of MXene electrodes and measure the thickness. The cross section of MXene film was observed using scanning electron microscopy (SEM; Zeiss Supra 50VP, Germany). The electrical conductivity of MXene films was measured using the 4-point probe instrument (ResTest, Jandel Engineering Ltd., Bedfordshire, U.K.), with probe distance of 1 mm. An average value was taken from 3 different locations on the film. The in-situ Raman and XRD measurements were carried out during the CV scanning at 2 mV s⁻¹. The electrochemical tests were conducted at room temperature using a BioLogic SP 150 potentiostat.

A vector network analyzer (VNA; 8720ES, Agilent, USA) with a WR-90 rectangular waveguide in the frequency range of 8.2−12.4 GHz was used to measure S parameters of MXene devices during the CV scanning at 10 mV s⁻¹. The device was mounted onto the sample holder and then tightly fixed with clamps.

The EMI shielding effectiveness (SE) was calculated based on S parameters (S₁₁ and S₂₁). The transmission power (T; T=|S₂₁|²), reflectivity power (R; R=|S₁₁|²), and absorption power (A) meet A+R+T=1. The total EMI shielding effectiveness (SEₜₒₜₐₗ), reflection effectiveness (SE_{R}) and absorption effectiveness (SE_{A}) associated with the incident wave P₁ and transmitted wave P_{T}, are calculated as follows.

$$S {E}_{t o t a l} = 10 {log}_{10} ( \frac{1}{T} ) \qquad ( 1 )$$

$$S {E}_{R} = 10 {log}_{10} ( \frac{1}{1 - R} ) \qquad ( 2 )$$

$$S {E}_{A} = 10 {log}_{10} ( \frac{1 - R}{T} ) \qquad ( 3 )$$

### REFERENCES

1. M. S. Ergoktas et al., Multispectral graphene-based electro-optical surfaces with reversible tunability from visible to microwave wavelengths. Nat. Photon. 15, 493−498 (2021).
2. X. A. Zhang et al., Dynamic gating of infrared radiation in a textile. Science 363, 619-623 (2019).
3. M. Han et al., Anisotropic MXene Aerogels with a Mechanically Tunable Ratio of Electromagnetic Wave Reflection to Absorption. Adv. Opt. Mater. 7, 1900267 (2019).
4. T. Inoue, M. De Zoysa, T. Asano, S. Noda, Realization of dynamic thermal emission control. Nature materials 13, 928 (2014).
5. A. VahidMohammadi, J. Rosen, Y. Gogotsi, The world of two-dimensional carbides and nitrides (MXenes). Science 372, eabfl581 (2021).
6. B. Anasori, M. R. Lukatskaya, Y. Gogotsi, 2D metal carbides and nitrides (MXenes) for energy storage. Nature Reviews Materials 2, 16098 (2017).

### Aspects

The following Aspects are illustrative only and do not limit the scope of the present disclosure or the appended claims. Any part or parts of any one or more Aspects can be combined with any part or parts of any one or more other Aspects.

Aspect 1. A tunable shielding component, comprising: a first portion of MXene; a second portion of MXene; and a separator disposed between the first portion of MXene and the second portion of MXene, the separator having an electrolyte disposed therein.

Aspect 2. The tunable shielding component of Aspect 1, further comprising a potential source in electronic communication with at least one of the first portion of MXene and the second portion of MXene.

Aspect 3. The tunable shielding component of any one of Aspects 1-2, wherein the separator comprises a membrane, the membrane optionally comprising polypropylene, cellulose ester, polyvinylidene difluoride (PVDF), or any combination thereof.

Aspect 4. The tunable shielding component of any one of Aspects 1-3, wherein the electrolyte comprises a halide, an acidic electrolytes (optionally comprising H₂SO₄ or H₃PO₄), a water-in-salt electrolyte (optionally comprising saturated LiCl or LiBr); a basic electrolyte (optionally comprising KOH, LiOH, or NaOH); an organic electrolyte (optionally comprising lithium bis(trifluoromethylsulfonyl) amine (LiTFSI) or 1-ethyl-3-methylimidazolium bis(trifluoromethylsulfonyl)imide (EMIMTFSI) in propylene carbonate (PC), acetonitrile (ACN) or dimethyl sulfoxide (DMSO)).

Aspect 5. The tunable shielding component of any one of Aspects 1-4, wherein the first portion of MXene and the second portion of MXene comprise a common MXene material.

Aspect 6. The tunable shielding component of any one of Aspects 1-4, wherein the first portion of MXene and the second portion of MXene comprise different MXene materials.

Aspect 7. The tunable shielding component of any one of Aspects 1-5, wherein the first portion of MXene, the separator, and the second portion of MXene together define a total thickness of from about 100 nm to about 100 micrometers, optionally from about 10 micrometers to about 500 micrometers.

Aspect 8. The tunable shielding component of any one of Aspects 1-7, wherein at least one of the first MXene portion and the second MXene portion has a thickness in the range of from about 10 to about 1000 nm.

Aspect 9. The tunable shielding component of any one of Aspects 1-8, wherein the tunable shielding component exhibits a changed EMI SE when a voltage is applied.

Aspect 10. The tunable shielding component of any one of Aspects 1-9, wherein the tunable shielding component exhibits a baseline EMI SE when zero potential is applied and a first EMI SE when a first potential is applied, the baseline and first EMI SEs differing by from about 1 to about 20 dB.

Aspect 11. The tunable shielding component of Aspect 10, wherein the baseline and first EMI SEs differ by from about 2 to about 10 dB, from about 3 to about 10 dB, from about 4 to about 10 dB, from about 5 to about 10 dB, or from about 6 to about 10 dB.

Aspect 12. The tunable shielding component of Aspect 10, wherein the baseline and first EMI SEs differ by from about 1 to about 20 dB, 3 to about 7 dB, from about 3 to about 6 dB, from about 3 to about 5 dB.

Aspect 13. The tunable shielding component of any one of Aspects 1-12, wherein the tunable shielding component maintains an essentially constant EMI SE following 500 electrochemical cycles at 20 mV si with 1M H₂SO₄ as the electrolyte.

Aspect 14. An electronic device, comprising a tunable shielding component according to any one of Aspects 1-13.

Aspect 15. The electronic device of Aspect 14, wherein the electronic device comprises a mobile communications device, a microphone, or both.

Aspect 16. A method, comprising applying a potential to a tunable shielding component according to any one of Aspects 1-13 so as to effect a change in the EMI SE of the tunable shielding component.

Aspect 17. The method of Aspect 16, where the potential is less than about 5 V (absolute value).

Aspect 18. The method of any one of Aspects 16-17, wherein the change in the EMI SE of the tunable shielding component is from about 2 to about 10 dB, from about 3 to about 10 dB, from about 4 to about 10 dB, from about 5 to about 10 dB, or from about 6 to about 10 dB.

Aspect 19. The method of Aspect 18, wherein the change in the EMI SE of the tunable shielding component is from about 2 to about 7 dB.

Aspect 20. The method of any one of Aspects 16-19, wherein the potential is applied so as to oxidize at least one of the first and second portions of MXene and effect a reduction in EMI SE of the tunable shielding component of from about 1 to 40 dB, the reduction optionally being irreversible.

Aspect 21. The method of any one of Aspects 16-20, wherein the tunable shielding component is operated as an EMI shielding switch.

1. A tunable shielding component, comprising:
a first portion of MXene;
a second portion of MXene; and
a separator disposed between the first portion of MXene and the second portion of MXene,
the separator having an electrolyte disposed therein.

2. The tunable shielding component of claim 1, further comprising a potential source in electronic communication with at least one of the first portion of MXene and the second portion of MXene.

3. The tunable shielding component of claim 1, wherein the separator comprises a membrane, the membrane optionally comprising polypropylene, cellulose ester, polyvinylidene difluoride (PVDF), or any combination thereof.

4. The tunable shielding component of claim 1, wherein the electrolyte comprises a halide, an acidic electrolytes (optionally comprising H₂SO₄ or H₃PO₄), a water-in-salt electrolyte (optionally comprising saturated LiCl, LiBr); a basic electrolyte (optionally comprising KOH, LiOH, or NaOH); an organic electrolyte (optionally comprising lithium bis(trifluoromethylsulfonyl) amine (LiTFSI) or 1-ethyl-3-methylimidazolium bis(trifluoromethylsulfonyl)imide (EMIMTFSI) in propylene carbonate (PC), acetonitrile (ACN) or dimethyl sulfoxide (DMSO)).

5. The tunable shielding component of claim 1, wherein the first portion of MXene and the second portion of MXene comprise a common MXene material.

6. The tunable shielding component of claim 1, wherein the first portion of MXene and the second portion of MXene comprise different MXene materials.

7. The tunable shielding component of claim 1, wherein the first portion of MXene, the separator, and the second portion of MXene together define a total thickness of from about 100 nm to about 100 micrometers, optionally from about 10 micrometers to about 500 micrometers.

8. The tunable shielding component of claim 1, wherein at least one of the first MXene portion and the second MXene portion has a thickness in the range of from about 10 to about 1000 nm.

9. The tunable shielding component of claim 1, wherein the tunable shielding component exhibits a changed EMI SE when a voltage is applied.

10. The tunable shielding component of claim 1, wherein the tunable shielding component exhibits a baseline EMI SE when zero potential is applied and a first EMI SE when a first potential is applied, the baseline and first EMI SEs differing by from about 1 to about 20 dB.

11. The tunable shielding component of claim 10, wherein the baseline and first EMI SEs differ by from about 2 to about 10 dB, from about 3 to about 10 dB, from about 4 to about 10 dB, from about 5 to about 10 dB, or from about 6 to about 10 dB.

12. The tunable shielding component of claim 10, wherein the baseline and first EMI SEs differ by from about 1 to about 20 dB, 3 to about 7 dB, from about 3 to about 6 dB, from about 3 to about 5 dB.

13. The tunable shielding component of claim 1, wherein the tunable shielding component maintains an essentially constant EMI SE following 500 electrochemical cycles at 20 mV s⁻¹ with 1M H₂SO₄ as the electrolyte.

14. An electronic device, comprising a tunable shielding component according to claim 1.

15. The electronic device of claim 14, wherein the electronic device comprises a mobile communications device, a microphone, or both.

16. A method, comprising applying a potential to a tunable shielding component according to claim 1 so as to effect a change in the EMI SE of the tunable shielding component.

17. The method of claim 16, where the potential is less than about 5 V (absolute value).

18. The method of claim 16, wherein the change in the EMI SE of the tunable shielding component is from about 2 to about 10 dB, from about 3 to about 10 dB, from about 4 to about 10 dB, from about 5 to about 10 dB, or from about 6 to about 10 dB.

19. (canceled)

20. The method of claim 16, wherein the potential is applied so as to oxidize at least one of the first and second portions of MXene and effect a reduction in EMI SE of the tunable shielding component of from about 1 to 40 dB, the reduction optionally being irreversible.

21. The method of claim 16, wherein the tunable shielding component is operated as an EMI shielding switch.
